(19) United States
(12) Patent Application Publication
(10) Pub. No.: US 2026/0164591 A1
(43) Pub. Date: Jun. 11, 2026

(54) CHASSIS AND TRAY

(71) Applicant: Wiwynn Corporation, New Taipei City (TW)

(72) Inventors: Chih-Wei Chang, New Taipei City (TW); Yun-Ting Chung, New Taipei City (TW)

(73) Assignee: Wiwynn Corporation, New Taipei City (TW)

(21) Appl. No.: 19/278,770

(22) Filed: Jul. 23, 2025

(30) Foreign Application Priority Data
Dec. 11, 2024 (TW) 113148081

(51) Int. Cl. H05K 7/14

(52) U.S. Cl. CPC H05K 7/1489

(57) ABSTRACT

A chassis includes a casing and a tray. The tray is disposed in the casing. The tray includes a tray body, a lock member and an unlock member. The tray body has a bottom plate and a side wall. The lock member is pivotally connected to the bottom plate and the lock member is locked with the casing. The unlock member is pivotally connected to the side wall and the unlock member engages with the lock member. When the unlock member rotates toward a first direction to disengage from the lock member, the tray is able to move out of the casing and the lock member is able to be pushed by the casing to rotate toward a second direction, such that the lock member is unlocked from the casing. The first direction is perpendicular to the second direction.

### BACKGROUND OF THE INVENTION

### 1. Field of the Invention

The invention relates to a chassis and a tray and, more particularly, to a tray capable of saving space and a chassis equipped with the tray.

### 2. Description of the Prior Art

With the rise of big data, machine learning, the Internet of Things, and various network platforms, the demand for servers in life is getting higher and higher, wherein blade servers adopt a modular design, such that more servers can be accommodated in a specific space, and management and wiring can be simplified simultaneously. In general, a tray may be disposed in a chassis to carry the blade server. In order to prevent the tray from falling due to rapid removal and causing personal injury, a safety lock is usually disposed on the tray to lock the tray in the chassis. However, the conventional safety lock

of the tray occupies more space, such that the number of components disposed on the tray is limited.

### SUMMARY OF THE INVENTION

According to an embodiment of the invention, a chassis comprises a casing and a tray. The tray is disposed in the casing. The tray comprises a tray body, a lock member and an unlock member. The tray body has a bottom plate and a side wall. The lock member is pivotally connected to the bottom plate and the lock member is locked with the casing. The unlock member is pivotally connected to the side wall and the unlock member engages with the lock member. When the unlock member rotates toward a first direction to disengage from the lock member, the tray is able to move out of the casing and the lock member is able to be pushed by the casing to rotate toward a second direction, such that the lock member is unlocked from the casing. The first direction is perpendicular to the second direction.

According to another embodiment of the invention, a tray is adapted to be disposed in a casing. The tray comprises a tray body, a lock member and an unlock member. The tray body has a bottom plate and a side wall. The lock member is pivotally connected to the bottom plate and the lock member is locked with the casing. The unlock member is pivotally connected to the side wall and the unlock member engages with the lock member. When the unlock member rotates toward a first direction to disengage from the lock member, the tray is able to move out of the casing and the lock member is able to be pushed by the casing to rotate toward a second direction, such that the lock member is unlocked from the casing. The first direction is perpendicular to the second direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a chassis according to an embodiment of the invention.

FIG. 2 is a perspective view illustrating the chassis shown in FIG. 1 from another viewing angle.

FIG. 3 is a partial perspective view illustrating the chassis shown in FIG. 1.

FIG. 4 is an exploded view illustrating the chassis shown in FIG. 3.

FIG. 5 is a perspective view illustrating an unlock member shown in FIG. 3 rotating toward a first direction.

FIG. 6 is a perspective view illustrating a lock member shown in FIG. 5 rotating toward a second direction.

FIG. 7 is a perspective view illustrating a second return member shown in FIG. 6 driving the lock member to return.

FIG. 8 is a perspective view illustrating a first return member shown in FIG. 7 driving the unlock member to return.

FIG. 9 is a perspective view illustrating the lock member shown in FIG. 8 rotating toward a third direction.

### DETAILED DESCRIPTION

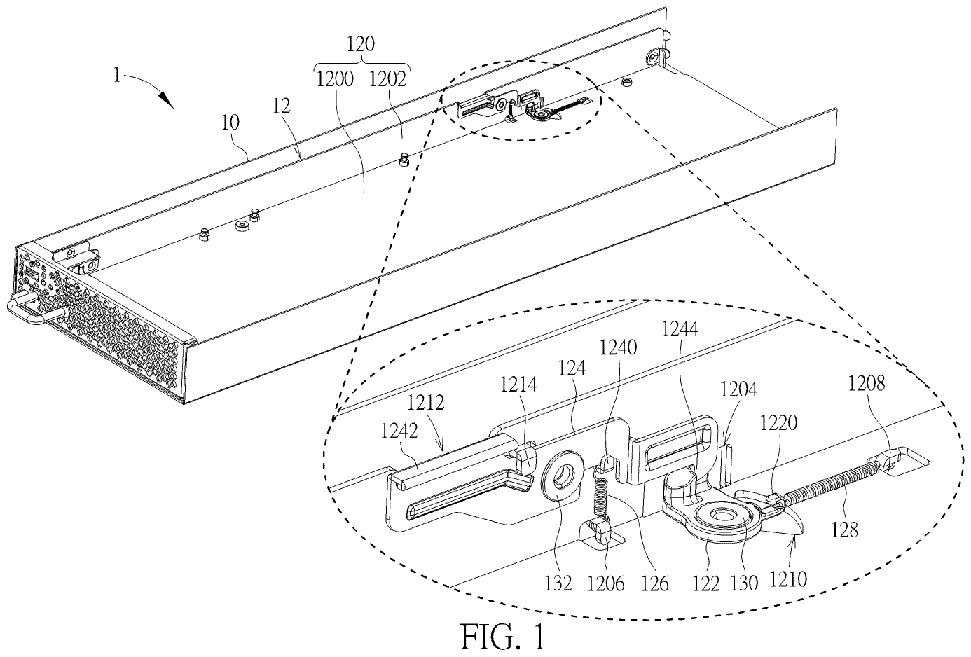

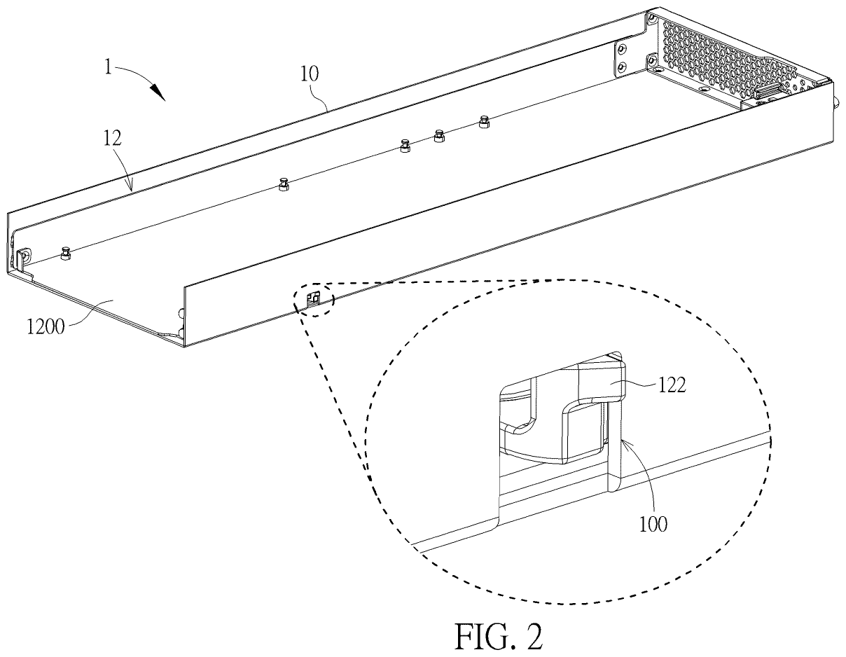

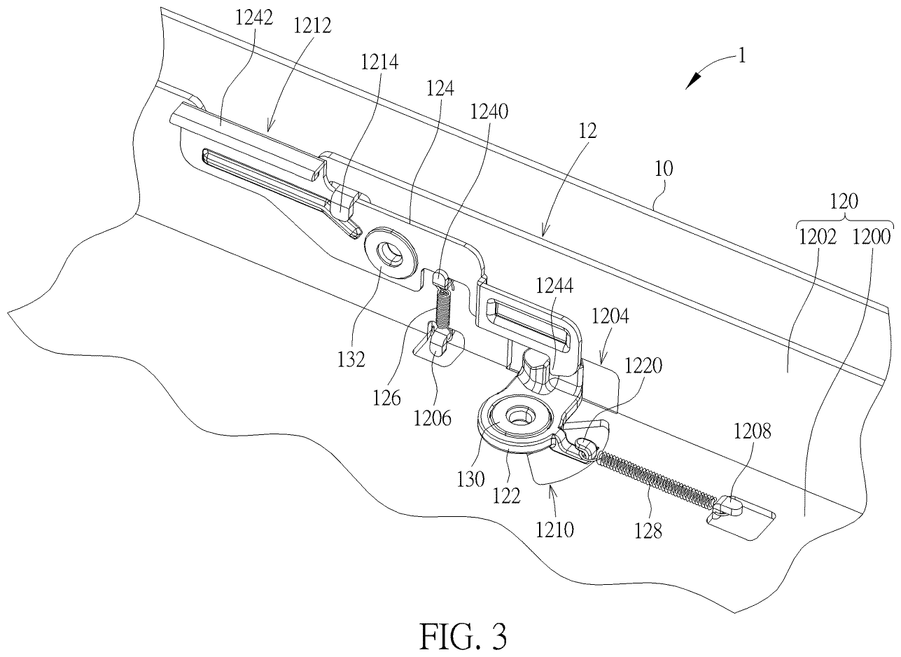

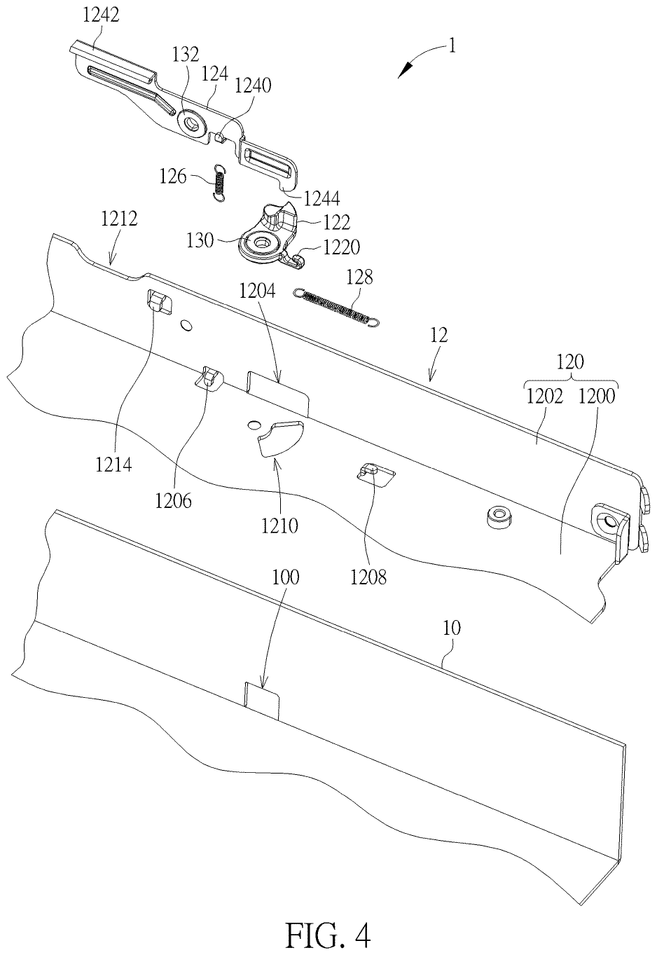

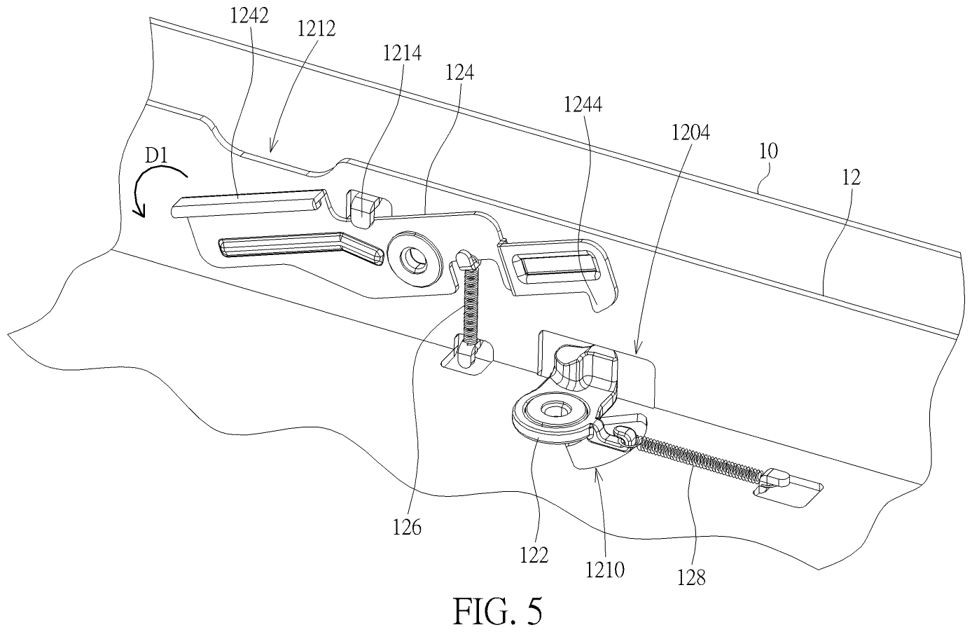

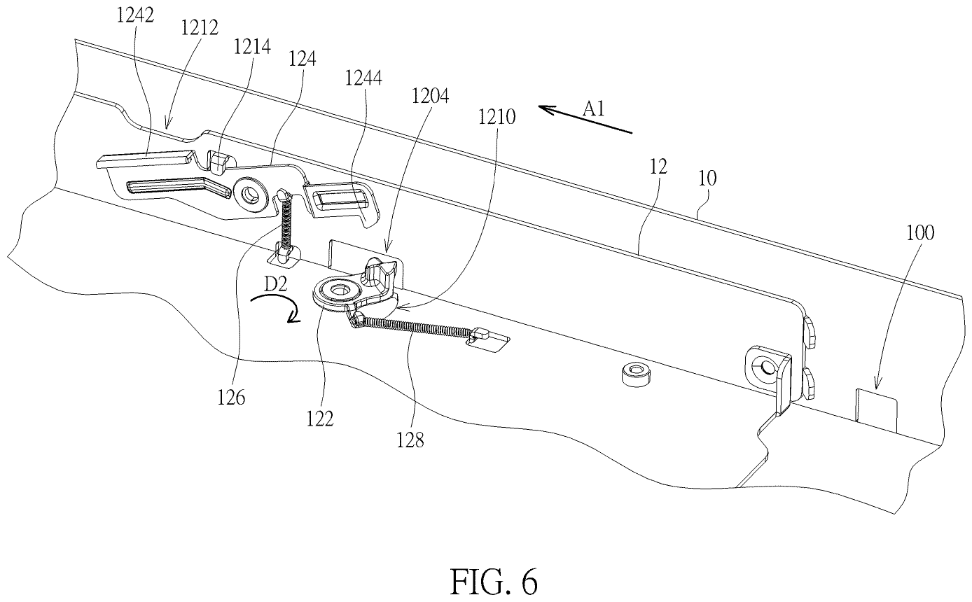

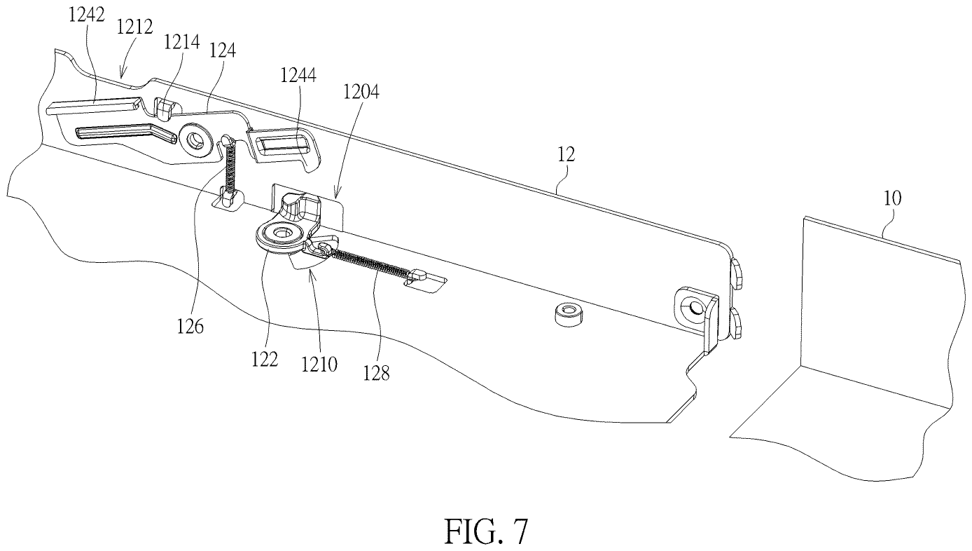

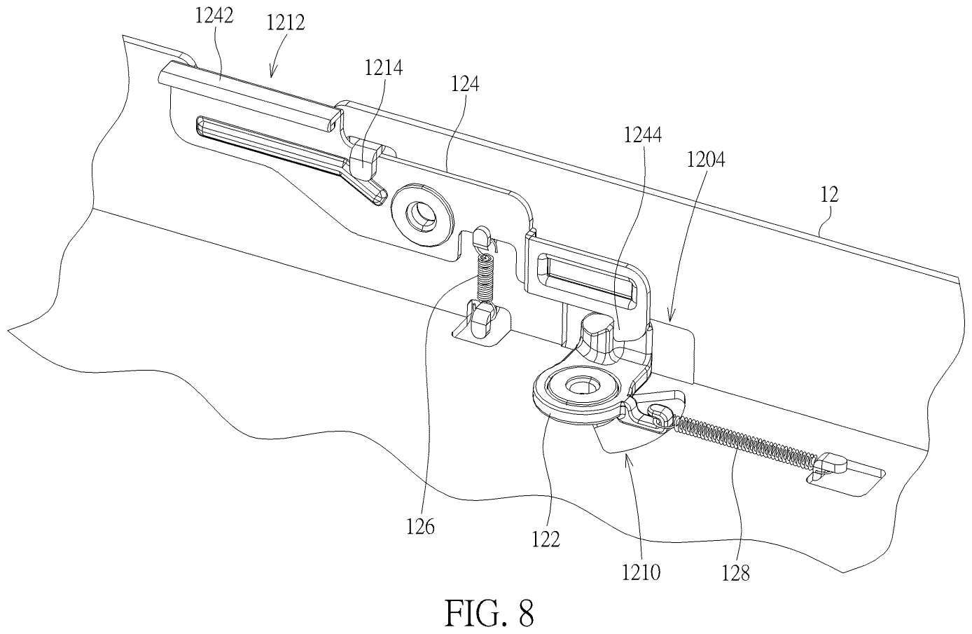

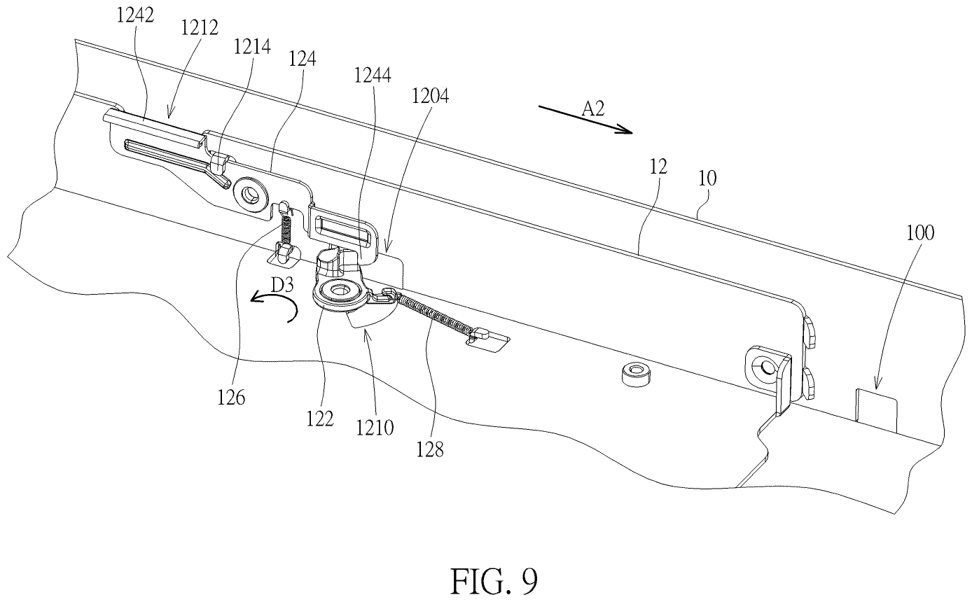

Referring to FIGS. 1 to 9, FIG. 1 is a perspective view illustrating a chassis 1 according to an embodiment of the invention, FIG. 2 is a perspective view illustrating the chassis 1 shown in FIG. 1 from another viewing angle, FIG. 3 is a partial perspective view illustrating the chassis 1 shown in FIG. 1, FIG. 4 is an exploded view illustrating the chassis 1 shown in FIG. 3, FIG. 5 is a perspective view illustrating an unlock member 124 shown in FIG. 3 rotating toward a first direction D1, FIG. 6 is a perspective view illustrating a lock member 122 shown in FIG. 5 rotating toward a second direction D2, FIG. 7 is a perspective view illustrating a second return member 128 shown in FIG. 6 driving the lock member 122 to return, FIG. 8 is a perspective view illustrating a first return member 126 shown in FIG. 7 driving the unlock member 124 to return, and FIG. 9 is a perspective view illustrating the lock member 122 shown in FIG. 8 rotating toward a third direction D3.

As shown in FIGS. 1 and 2, the chassis 1 comprises a casing 10 and a tray 12. The tray 12 may be used to carry a blade server, a multi-node server or other types of servers or electronic devices according to practical applications. Needless to say, the tray 12 may also be used to carry non-electronic components. The tray 12 is adapted to be disposed in the casing 10. It should be noted that the casing 10 illustrated in FIGS. 1 and 2 is only a part of a complete casing of the chassis 1.

As shown in FIGS. 3 and 4, the casing 10 comprises a lock hole 100 and the tray 12 comprises a tray body 120, a lock member 122, an unlock member 124, a first return member 126 and a second return member 128. In practical applications, a lock member 122, an unlock member 124, a first return member 126 and a second return member 128 may be disposed on each of two sides of the tray, and a lock hole 100 may be formed on each of two sides of the casing 10 correspondingly, such that the locking and unlocking of the tray 12 is more stable in operation. Needless to say, in some embodiments, a lock member 122, an unlock member 124, a first return member 126 and a second return member 128 may be disposed on one side of the tray only, a lock hole 100 may be formed on one side of the casing 10 correspondingly, and it depends on practical applications.

The tray body 120 has a bottom plate 1200 and a side wall 1202, wherein the side wall 1202 extends from the bottom plate 1200 upward. In this embodiment, the side wall 1202 may have a through hole 1204, wherein a position of the through hole 1204 corresponds to a position of the lock hole 100. The lock member 122 may be pivotally connected to the bottom plate 1200 by a pivot 130, and the unlock member 124 may be pivotally connected to the side wall 1202 by a pivot 132. The first return member 126 is connected to the unlock member 124 and the side wall 1202. In this embodiment, the unlock member 124 may have a connecting portion 1240 and the side wall 1202 may have another connecting portion 1206. Thus, two ends of the first return member 126 may be respectively connected to the connecting portion 1240 of the unlock member 124 and the connecting portion 1206 of the side wall 1202. The second return member 128 is connected to the lock member 122 and the bottom plate 1200. In this embodiment, the lock member 122 may have a connecting member 1220 and the bottom plate 1200 may have another connecting portion 1208. Thus, two ends of the second return member 128 may be respectively connected to the connecting portion 1220 of the lock member 122 and the connecting portion 1208 of the bottom plate 1200. In this embodiment, the bottom plate 1200 may have an avoidance hole 1210. The connecting portion 1220 of the lock member 122 may be accommodated in the avoidance hole 1210, so as to retain the openness of the space above the bottom plate 1200 to facilitate the placement of more components, layout or other configurations. Furthermore, the avoidance hole 1210 may be arc-shaped to allow the connecting portion 1220 to rotate in the avoidance hole 1210 along with the rotation of the lock member 122. In another embodiment, the connecting portion 1220 of the lock member 122 may also be located above the bottom plate 1200. At this time, the avoidance hole 1210 may be omitted.

In this embodiment, the unlock member 124 may have a press portion 1242 and the press portion 1242 may extend toward a direction parallel to the bottom plate 1200. The press portion 1242 may provide a larger area for a user to press, so as to facilitate the user to operate the unlock member 124. Accordingly, the invention may reduce the thickness of the main body of the unlock member 124, so as to retain the openness of the space above the bottom plate 1200 to facilitate the placement of more components, layout or other configurations. Furthermore, the side wall 1202 may have a concave portion 1212, wherein a position of the concave portion 1212 corresponds to a position of the press portion 1242. The concave portion 1212 is configured to provide an operating space for the user to press the press portion 1242 of the unlock member 124.

As shown in FIGS. 1 to 3, when the tray 12 is disposed in the casing 10, the unlock member 124 engages with the lock member 122 and the lock member 122 extends into the lock hole 100 to be locked with the casing 10. At this time, the tray 12 cannot be taken out of the casing 10. When a user wants to take the tray 12 out of the casing 10, the user needs to press the press portion 1242 of the unlock member 124 to drive the unlock member 124 to rotate toward a first direction D1 to disengage from the lock member 122, as shown in FIG. 5. At this time, the first return member 126 is stretched by the unlock member 124. When the unlock member 124 rotates toward the first direction D1 to disengage from the lock member 122, the tray 12 is able to move out of the casing 12. As shown in FIG. 6, when the user takes the tray 12 out of the casing 10 toward a direction of an arrow A1, the lock member 122 is able to be pushed by the casing 10 to rotate toward a second direction D2, such that the lock member 122 disengages from the lock hole 100 to be unlocked from the casing 10. At this time, the second return member 128 is stretched by the lock member 122. In this embodiment, the first direction D1 is perpendicular to the second direction D2. By means of the rotations of the unlock member 124 and the lock member 122 in the first direction D1 and the second direction D2 respectively, the invention can effectively reduce the rotation radius of the lock member 122 above the bottom plate 1200, so as to improve the utilization of the space above the bottom plate 1200 for installing more components, layout or other configurations.

As shown in FIG. 7, after the tray 12 is taken out of the casing 10, the second return member 128 drives the lock member 122 to return. Then, as shown in FIG. 8, when the unlock member 124 is released, the first return member 126 drives the unlock member 124 to return, such that the unlock member 124 engages with the lock member 122. In this embodiment, the unlock member 124 may have an engaging hook 1244, wherein the engaging hook 1244 is configured to engage with the lock member 122. In this embodiment, the side wall 1202 may have a stop portion 1214. When the unlock member 124 engages with the lock member 122, the stop portion 1214 is configured to stop the unlock member 124 to prevent the engaging hook 1244 from falling down to affect the engaging function.

During assembly, the user may directly place the tray 12 into the casing 10. As shown in FIG. 9, when the tray 12 is placed into the casing 10 toward a direction of an arrow A2, the lock member 122 is able to be pushed by the casing 10 to rotate toward a third direction D3. At this time, the second return member 128 is stretched by the lock member 122. In this embodiment, the third direction D3 is opposite to the second direction D2 (as shown in FIG. 6). Thus, when the unlock member 124 engages with the lock member 122, the unlock member 124 only restrains the lock member 122 from rotating toward the second direction D2 without restraining the lock member 122 from rotating toward the third direction D3. After the tray 12 is placed into the casing 10 completely, the second return member 128 drives the lock member 122 to return, such that the lock member 122 extends into the lock hole 100 to be locked with the casing 10, as shown in FIGS. 1 to 3.

In this embodiment, the first return member 126 and the second return member 128 may be, but are not limited to, extension springs. In another embodiment, the first return member 126 may also be a compression spring or a torsion spring. When the first return member 126 is a torsion spring, the torsion spring may be sleeved on the pivot 132 of the unlock member 124. In another embodiment, the first return member 126 and the second return member 128 may also be replaced by magnetic members (e.g. magnets), wherein the magnetic members may be disposed at appropriate positions corresponding to the lock member 122 and the unlock member 124, so as to drive the lock member 122 and the unlock member 124 to return by magnetic force.

As mentioned in the above, by means of the rotations of the unlock member and the lock member in two different directions respectively, the invention can effectively reduce the rotation radius of the lock member 122 above the bottom plate, so as to improve the utilization of the space above the bottom plate for installing more components, layout or other configurations.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chassis comprising:
a casing; and
a tray disposed in the casing, the tray comprising:
a tray body having a bottom plate and a side wall;
a lock member pivotally connected to the bottom plate, the lock member being locked with the casing; and
an unlock member pivotally connected to the side wall, the unlock member engaging with the lock member;
wherein, when the unlock member rotates toward a first direction to disengage from the lock member, the tray is able to move out of the casing and the lock member is able to be pushed by the casing to rotate toward a second direction, such that the lock member is unlocked from the casing; the first direction is perpendicular to the second direction.

2. The chassis of claim 1, wherein, when the tray is placed into the casing, the lock member is able to be pushed by the casing to rotate toward a third direction; the third direction is opposite to the second direction.

3. The chassis of claim 1, wherein the tray further comprises a first return member connected to the unlock member and the side wall.

4. The chassis of claim 1, wherein the tray further comprises a second return member connected to the lock member and the bottom plate.

5. The chassis of claim 4, wherein the bottom plate has an avoidance hole, the lock member has a connecting portion, the second return member is connected to the connecting portion, and the connecting portion is accommodated in the avoidance hole.

6. The chassis of claim 5, wherein the avoidance hole is arc-shaped to allow the connecting portion to rotate in the avoidance hole.

7. The chassis of claim 1, wherein the side wall has a stop portion; wherein, when the unlock member engages with the lock member, the stop portion stops the unlock member.

8. The chassis of claim 1, wherein the unlock member has a press portion and the press portion extends toward a direction parallel to the bottom plate.

9. The chassis of claim 8, wherein the side wall has a concave portion and a position of the concave portion corresponds to a position of the press portion.

10. A tray adapted to be disposed in a casing, the tray comprising:
a tray body having a bottom plate and a side wall;
a lock member pivotally connected to the bottom plate, the lock member being locked with the casing; and
an unlock member pivotally connected to the side wall, the unlock member engaging with the lock member;
wherein, when the unlock member rotates toward a first direction to disengage from the lock member, the tray is able to move out of the casing and the lock member is able to be pushed by the casing to rotate toward a second direction, such that the lock member is unlocked from the casing; the first direction is perpendicular to the second direction.

11. The tray of claim 10, wherein, when the tray is placed into the casing, the lock member is able to be pushed by the casing to rotate toward a third direction; the third direction is opposite to the second direction.

12. The tray of claim 10, further comprising a first return member connected to the unlock member and the side wall.

13. The tray of claim 10, further comprising a second return member connected to the lock member and the bottom plate.

14. The tray of claim 13, wherein the bottom plate has an avoidance hole, the lock member has a connecting portion, the second return member is connected to the connecting portion, and the connecting portion is accommodated in the avoidance hole.

15. The tray of claim 14, wherein the avoidance hole is arc-shaped to allow the connecting portion to rotate in the avoidance hole.

16. The tray of claim 10, wherein the side wall has a stop portion; wherein, when the unlock member engages with the lock member, the stop portion stops the unlock member.

17. The tray of claim 10, wherein the unlock member has a press portion and the press portion extends toward a direction parallel to the bottom plate.

18. The tray of claim 17, wherein the side wall has a concave portion and a position of the concave portion corresponds to a position of the press portion.
